(19) United States
(12) Patent Application Publication
(10) Pub. No.: US 2014/0346629 A1
(43) Pub. Date: Nov. 27, 2014

(54) IMAGING ELEMENT

(71) Applicant: FUJIFILM Corporation, Tokyo (JP)

(72) Inventors: Masayuki NAYA, Ashigarakami-gun (JP); Takeharu TANI, Ashigarakami-gun (JP)

(21) Appl. No.: 14/457,834

(22) Filed: Aug. 12, 2014

Related U.S. Application Data
(63) Continuation of application No. PCT/JP2013/000658, filed on Feb. 7, 2013.

(30) Foreign Application Priority Data
Feb. 13, 2012 (JP) 2012-028329

(51) Int. Cl. H01L 27/146

(52) U.S. Cl. CPC H01L 27/1463; H01L 27/14621
USPC 257/432

(57) ABSTRACT

An imaging element includes: a plurality of photoelectric converting elements that receive irradiation of light and convert the light into electrical charges; and a color filter layer which has a red filter, a green filter, and a blue filter which are respectively provided for the photoelectric converting elements. Partition walls having a lower refractive index than those of the red filter, the green filter, and the blue filter are provided only around the peripheries of the red filters.

### CROSS REFERENCE TO RELATED APPLICATIONS

The present application is a Continuation of PCT International Application No. PCT/JP2013/000658 filed on Feb. 7, 2013, which claims priority under 35 USC §119 (a) to Japanese Patent Application No. 2012-028329 filed on Feb. 13, 2012. Each of the above application(s) is hereby expressly incorporated by reference in its entirety, into the present application.

### TECHNICAL FIELD

The present invention is related to an imaging element equipped with a color filter layer that has red filters, green filters, and blue filters.

### BACKGROUND ART

Conventionally, various imaging elements such as CMOS's (Complementary Metal Oxide Semiconductors) and CCD's (Charge Coupled Devices), in which a plurality of photoelectric converting elements that convert light into electrical charges are arrayed, have been proposed.

There are also known imaging elements provided with primary color filters, which are combinations of red filters, blue filters, and green filters.

Here, light that enters an imaging element provided with a color filter such as that described above are not necessarily perpendicular to the light receiving surface thereof nor collimated. Accordingly, there are cases in which light that enters the light receiving surface from an oblique direction passes through one color filter obliquely, and then enters an adjacent color filter before entering a photoelectric converting element. There is a problem that so called cross talk is generated in such cases.

As an example of a measure for solving such cross talk problems, Japanese Unexamined Patent Document No. 2009-111225 proposes to provide partition walls having a refractive index lower than those of the color filters at the boundaries of each of the color filters which are provided for each photoelectric converting element.

### DISCLOSURE OF THE INVENTION

However, in imaging elements provided with partition walls at all of the boundaries among red filters, blue filters, and green filters as disclosed in Japanese Unexamined Patent Document No. 2009-111225, there is a problem that the amount of received light will decrease corresponding to the area occupied by the partition walls on the light receiving surface of the imaging elements.

In addition, in the case that partition walls are provided at all of the boundaries among red filters, blue filters, and green filters, it will become necessary to provide the partition walls at all four sides of small regions which are approximately the size of image pixels. Therefore, process loss due to defects in the partition walls will become likely to occur, resulting in increased costs.

The present invention has been developed in view of the foregoing circumstances. It is an object of the present invention to provide an imaging element in which light receiving efficiency is improved while suppressing cross talk of light which has passed through each color filter, without an increase in cost.

An imaging element of the present invention comprises:

a plurality of photoelectric converting elements that receive irradiation of light and convert the light into electrical charges; and

a color filter layer which has a red filter, a green filter, and a blue filter which are respectively provided for each of the photoelectric converting elements;

partition walls having a lower refractive index than those of the red filter, the green filter, and the blue filter being provided only around the peripheries of the red filters.

The imaging element of the present invention may be provided with mask members that absorb or reflect light, provided on the surfaces of the partition walls on the sides thereof that receive the light.

In addition, the difference between the refractive index of the blue filter and the refractive index of the green filter may be 0.05 or less through the entire wavelength range from 500 nm to 650 nm.

In addition, the difference between the refractive index of the blue filter and the refractive index of the red filter may be 0.15 or less through the entire wavelength range from 500 nm to 650 nm.

In addition, the refractive index of the partition walls may be 1.4 or less.

In addition, the thickness of the partition walls in a direction perpendicular to the thickness direction of the color filter layer may be within a range from 50 nm to 200 nm.

In addition, the color filter layer may be constituted by green filter rows, in which a plurality of the green filters are arranged in a single row, and red/blue filter rows, in which red filter sets constituted by two of the red filters and blue filter sets constituted by two of the blue filters are alternately arranged in a single row, the green filter rows and the red/blue filter rows being alternately provided in a direction perpendicular to the direction in which the green filter rows and the red/blue filter rows extend.

In addition, the partition walls may be formed by a low refractive index material having a lower refractive index than the refractive indices of the red filter, the green filter, and the blue filter.

Alternatively, the partition walls may be formed by spaces.

The imaging element of the present invention comprises the plurality of photoelectric converting elements that receive irradiation of light and convert the light into electrical charges; and the color filter layer which has a red filter, a green filter, and a blue filter which are respectively provided for each of the photoelectric converting elements. The partition walls having a lower refractive index than those of the red filter, the green filter, and the blue filter are provided only around the peripheries of the red filters. Therefore, light receiving efficiency can be improved compared to a case in which partition walls are provided at all of the boundaries among red filters, blue filters, and green filters.

In addition, process loss due to defects in the partition walls can be reduced, resulting in decreased costs.

In addition, the influence of cross talk caused by light entering red filters from green filters and blue filters is much greater than the influence of cross talk between green filters and blue filters, as will be described later. Therefore, the effect of suppressing cross talk can be sufficiently obtained, even if the partition walls are provided only around the peripheries of the red filters as in the imaging element of the present invention.

In addition, in the case that mask members that absorb or reflect the light are provided on the surfaces of the partition walls on the sides thereof that receive the light in the imaging element of the present invention, cross talk caused by light that enters the partition walls leaking into the red filters, the green filters, or the blue filters can be prevented.

### BRIEF DESCRIPTION OF THE DRAWING

FIG. 1 is a sectional diagram that schematically illustrates the configuration of an imaging element according to an embodiment of the present invention.

FIG. 2 is a plan view of the imaging element of FIG. 1.

FIG. 3 is a diagram that illustrates an example of the results of a simulation of the light entrance efficiencies of red filters, green filters, and blue filters in the case that partition walls are provided only at the peripheries of the red filters.

FIG. 4 is a diagram that illustrates an example of the results of a simulation of the light entrance efficiencies of red filters, green filters, and blue filters in the case that no partition walls are provided.

FIG. 5 is a diagram that illustrates the results of a simulation of the light entrance efficiencies of red filters, green filters, and blue filters in the case that partition walls are provided at the boundaries among all of the filters.

FIG. 6 is a diagram that illustrates refractive indices of red filters, green filters, and blue filters in a typical imaging element.

FIG. 7 is a diagram that illustrates another example of the results of a simulation of the light entrance efficiencies of red filters, green filters, and blue filters in the case that partition walls are provided only at the peripheries of the red filters.

FIG. 8 is a diagram that schematically illustrates a state in which a first coloring layer is formed.

FIG. 9 is a diagram that schematically illustrates a state in which an opening is formed in photoresist on the first coloring layer.

FIG. 10 is a diagram that schematically illustrates a state in which an opening is formed in a region of the first coloring layer at which a second coloring layer is to be formed.

FIG. 11 is a diagram that schematically illustrates a state in which the second coloring layer has been formed so as to cover the first coloring layer and the opening.

FIG. 12 is a diagram that schematically illustrates the first coloring layer and the second coloring layer formed as patterns.

FIG. 13 is a diagram that schematically illustrates a color filter array formed by the three colors R, G, and B.

FIG. 14 is a sectional diagram that illustrates a state in which a lattice shaped space pattern is formed on the color filter array.

FIG. 15 is a sectional diagram that illustrates a state in which gaps are formed among color filter layers.

FIG. 16 is a diagram that illustrates another example of a color filter layer.

FIG. 17 is a plan view of an imaging element having mask members on partition walls.

### BEST MODE FOR CARRYING OUT THE INVENTION

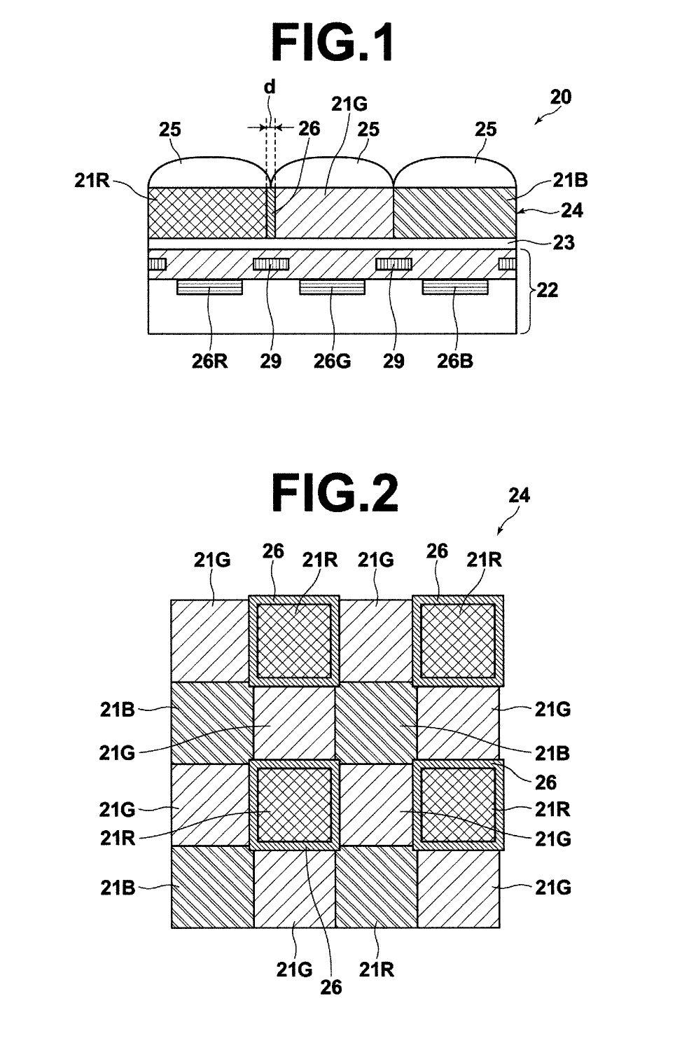

Hereinafter, an imaging element according to an embodiment of the present invention will be described in detail with reference to the attached drawings. FIG. 1 is a sectional diagram that schematically illustrates the configuration of the imaging element according to the embodiment of the present invention.

The imaging element 20 of the present embodiment is equipped with: a semiconductor substrate 22 having photodiodes (photoelectric converting elements) 26R, 26G, and 26B that generate electrical charges when irradiated with light; a device protecting film 23 formed on the semiconductor substrate 22; a color filter layer 24 having red filters 21R, green filters 21G, blue filters 21B, and partition walls 26 formed at the peripheries of the red filters 21R; and a microlens array 25 constituted by a great number of lenses provided to correspond to each of the red filters 21R, the green filters 21G, and the blue filters 21B, as illustrated in FIG. 1.

The imaging element 20 is configured such that light which is irradiated onto the imaging element 20 is focused by each lens of the microlens array 25, enters the red filters 21R, the green filters 21G, and the blue filters 21B corresponding to each lens, and the light which has passed through the red filters 21R, the green filters 21G, and the blue filters 21B enters the photodiodes 26R, 26G, and 26B corresponding thereto.

The semiconductor substrate 22 is equipped with the plurality of photodiodes 26R, 26G, and 26B that constitute a light receiving area as described above. In addition, the semiconductor substrate 22 is also equipped with transfer electrodes 29 constituted by polysilicon or the like. Further, the semiconductor substrate 22 is equipped with a light shielding film (now shown) provided such that only the light receiving surfaces of the photodiodes 26R, 26G, and 26B are exposed. The light shielding film is formed by tungsten or the like.

As described above, the color filter layer 24 has the red filters 21R, the green filters 21G, the blue filters 21B, and the partition walls 26 which are provided only at the peripheries of the red filters 21R.

The partition walls 26 are formed by a low refractive index material having a lower refractive index than the refractive indices of the red filters 21R, the green filters 21G, and the blue filters 21B. In the case that oblique light enters the imaging element 20, the partition walls reflect such oblique light. The partition walls 26 are formed by a dry etching method as will be described later, such that the wall surfaces thereof are substantially parallel to a line normal to the semiconductor substrate 22. Note that in the present embodiment, the partition walls are provided only at the peripheries of the red filters 21R. The reason why this configuration is adopted will be described later.

FIG. 2 is a plan view of the color filter 24 of the present embodiment as viewed from above the semiconductor substrate 22 (in the direction of the line normal thereto). Note that in FIG. 1, the red filter 21R, the green filter 21G, and the blue filter 21B are illustrated arrayed in a single row. However, this illustration is only to facilitate understanding of the description thereof, and the red filters 21R, the green filters 21G, and the blue filters 21B of the present embodiment are actually arranged as illustrated in FIG. 2.

The refractive indices of the red filters 21R, the green filters 21G, and the blue filters 21B, which are formed by being colored and cured, are within an approximate range from 1.55 to 1.85. Accordingly, it is desirable for the refractive index n of the low refractive index material that forms the partition walls 26 to be 1.5 or less. Thereby, a difference in refractive indices can be provided between the color filters and the partition walls 26, and the partition walls 26 will be effective reflectors of light. It is more preferable for the refractive index n of the partition walls 26 to be 1.45 or less, and most preferably 1.4 or less, from the viewpoint of obtaining a greater difference in refractive indices between the color filters and the partition walls 26.

Examples of low refractive index materials having refractive indices as described above include: glass (n=1.52); a porous layer of SiO₂ film (silica: n=1.3˜1.35); a fluorine series polymer (n=1.3˜1.4), and a siloxane polymer (n=1.5). In addition, an example of a material for forming the aforementioned porous layer of SiO₂ film is a coating material in which a porous layer matrix is formed by a sol gel method. An example of a fluorine series polymer is the JN series of OPSTAR low refractive index materials by JSR Corporation. An example of a siloxane polymer is the NR series polymer by Toray, Incorporated.

It is desirable for the thickness d of the partition walls 26 (refer to FIG. 1) in the direction perpendicular to the direction of the thickness of the color filter layer 24 to be 50 nm or greater and 200 nm or less. In the case that the thickness d of the partition walls 26 is within the above range, an area ratio of the color filter with respect to the entire region through which light passes can be secured, and the color purity of each of the color filters can be improved. It is more preferable for the wall thickness to be 80 nm or greater and 150 nm or less.

In addition, the red filters 21R, the green filters 21G, and the blue filters 21B are formed by colored compositions. It is desirable for the red filters 21R, the green filters 21G, and the blue filters 21B to be formed by thermocurable compositions.

For example, in the case that photocurable compositions are employed, it will become necessary for the compositions to contain an alkali soluble resin which is soluble in photosensitive curing components such as a photoinitiating agent and a monomer. As a result, the amount of a coloring agent within all solid components will become relatively low, and there is a demerit that the film thickness will become thick. In addition, because such compositions include photocurable components, the thickness of these components influences the film thickness of the color filter, and it will become difficult to realize a thin film. As a result, there are problems such as color shading deteriorating and color mixing becoming more likely to occur.

In contrast, in the case that thermocurable compositions are employed as the coloring compositions, the use of photocurable components can be reduced or eliminated. By decreasing the amount of or eliminating photocurable components, the concentration of a coloring agent can be increased. Accordingly, patterns can be formed as thin films while maintaining transmitted spectra.

By adopting the configuration described above, the imaging element 20 itself can be formed thin, and the light collecting efficiency of light that enters the imaging element 20 can be improved. In addition, by forming the color filter layer 24 to be thin, color shading properties are improved, and the device properties can be improved.

The aforementioned coloring compositions may be selected from among known curable compositions. With respect to thermocurable compositions, that disclosed in Japanese Unexamined Patent Publication No. 2009-111225, for example, may be utilized. However, although it is desirable for a thermocurable composition to be employed in the imaging element of the present invention, use of a photocurable composition is not excluded from the present invention.

In addition, in the imaging element 20 of the present embodiment, the partition walls 26 are provided only at the peripheries of the red filters 21R, and no partition walls 26 are provided at the boundaries among the green filters 21G and the blue filters 21B. The reason why this configuration is adopted will be described below.

Generally, the refractive index with respect to light of the red filters 21R is higher than those of other colored filters. It was found that for this reason, the influence of cross talk caused by light entering the red filters 21R from the green filters 21G and the blue filters 21B was greater due to the waveguiding effect of light. The partition walls 26 are provided only at the peripheries of the red filters 21R in the present embodiment, because the influence of cross talk between the green filters 21G and the blue filters 21B is small. Thereby, the light loss caused by providing the partition walls 26 are limited to the pixels corresponding to the red filters 21R, and the light receiving efficiency of the imaging element as a whole can be improved. In addition, defects in the partition walls 26 can be decreased, resulting in a reduction in cost.

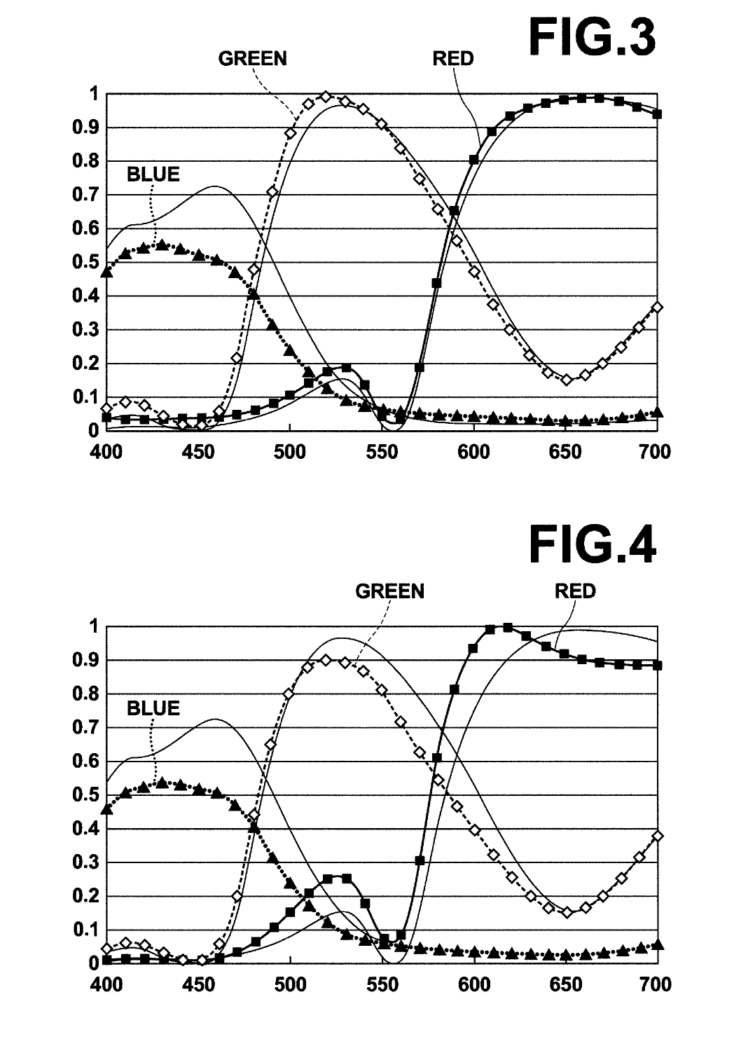

Here, FIG. 3 illustrates the results of a simulation of the light entrance efficiencies of the red filters 21R, the green filters 21G, and the blue filters 21B in the case that the partition walls 26 are provided only at the peripheries of the red filters 21R. Note that here, the light entrance efficiencies refer to the percentages of light that enter each of the filters, pass therethrough, and reach the photodiodes. In addition, the curves drawn by the thin solid lines in FIG. 3 represent ideal spectral transmittance rates of the red filters, the green filters, and the blue filters.

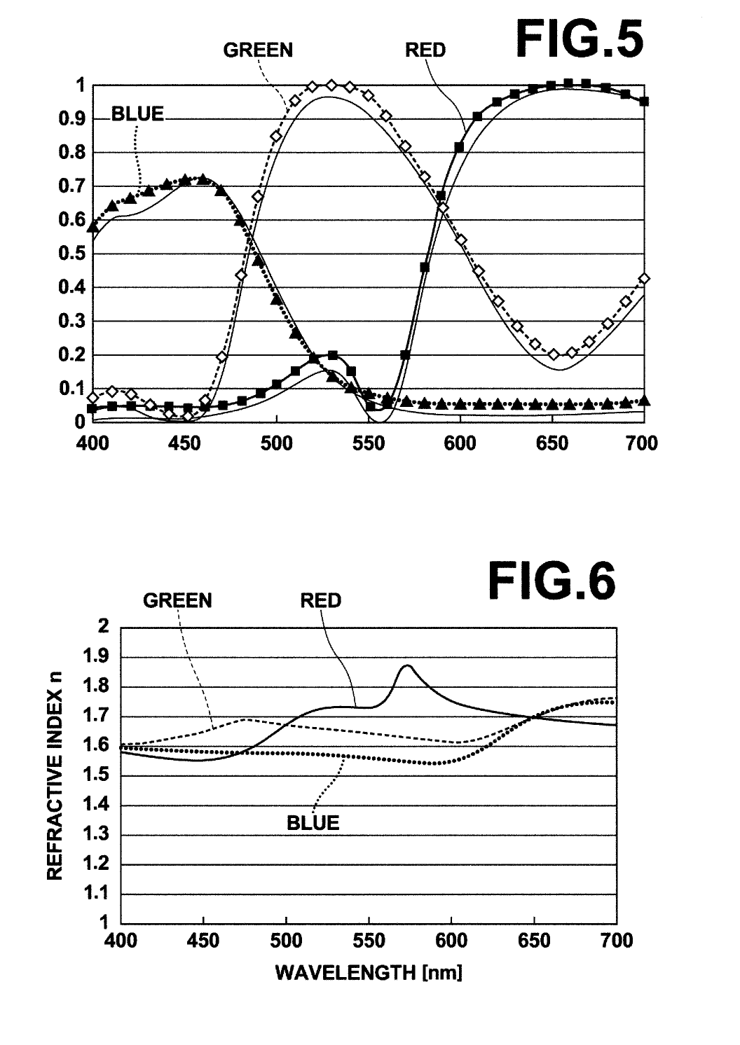

For the purposes of comparison, FIG. 4 illustrates the results of a simulation of the light entrance efficiencies of red filters, green filters, and blue filters in the case that no partition walls are provided, and FIG. 5 illustrates the results of a simulation of the light entrance efficiencies of red filters, green filters, and blue filters in the case that the partition walls 26 are provided at the boundaries among all of the filters.

From the simulation results illustrated in FIG. 3 through FIG. 5, it can be understood that it is better to provide the partition walls 26 at the boundaries among all of the filters (FIG. 5) from the viewpoint of the light entrance efficiencies of the red filters, the green filters, and the blue filters. However, it can also be understood that the light entrance efficiency of the green filters 21G are sufficiently improved in the case that the partition walls 26 are provided only at the peripheries of the red filters 21R as in the present embodiment (FIG. 3), compared to the simulation results for the case that the partition walls are not provided at all (FIG. 4). In addition, it can be understood that color mixing at the red filters 21R, which occurs when no partition walls are provided, is improved as well.

Accordingly, it can be understood that it is preferable for the partition walls 26 to be provided only at the peripheries of the red filters 21R taking not only light entrance efficiency but also light loss caused by providing the partition walls 26 and the defects of the partition walls 26 into consideration.

Note that in the case that the partition walls 26 are provided only at the peripheries of the red filters 21R, the improvement in the light entrance efficiency of the blue filters 21B is small, as can be understood from the simulation results illustrated in FIG. 3. This is because generally, the refractive indices of the red filters, blue filters, and green filters have the relationship illustrated in FIG. 6. That is, the refractive index of the red filters is greater than the refractive index of the green filters, and the refractive index of the green filters is greater than the refractive index of the blue filters within a wavelength range from 500 nm to 650 nm, and light is likely to bond from blue to green and from blue to red.

Accordingly, it is desirable for the material of the blue filters 21B to be that which has a difference in refractive index of 0.05 or less from that of the green filters 21G through the entire wavelength range from 500 nm to 650 nm, in order to improve the light entrance efficiency of the blue filters 21B. Further, it is desirable for the material of the blue filters 21B to be that which has a difference in refractive index of 0.15 or less from that of the red filters 21R through the entire wavelength range from 500 nm to 650 nm. Known materials may be employed as the material of the filter having such differences in refractive index.

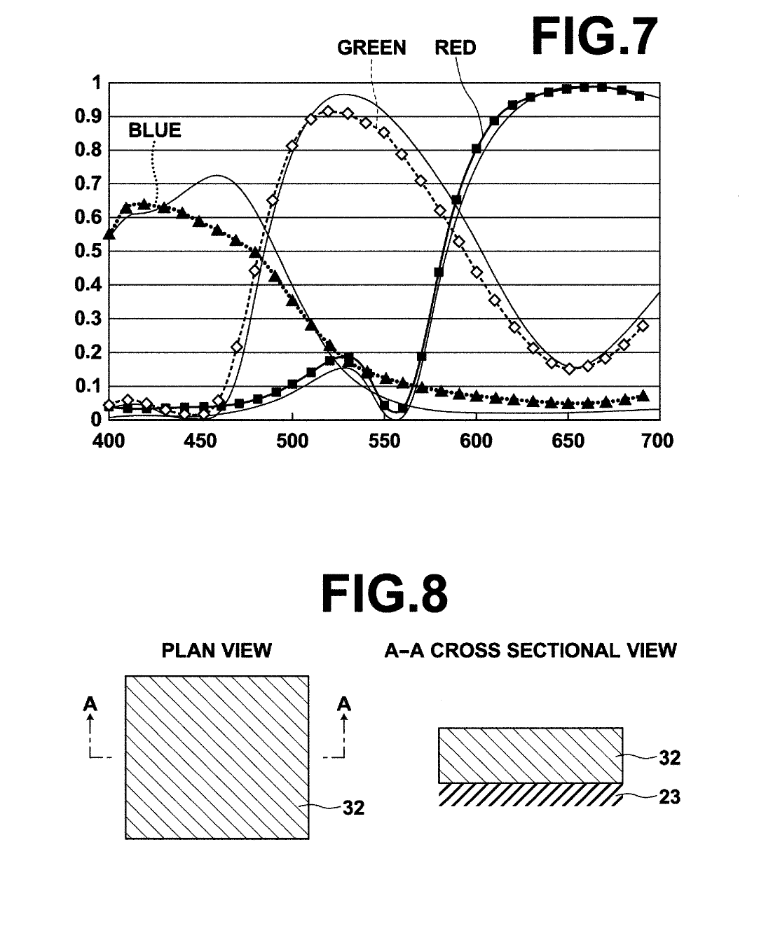

FIG. 7 illustrates the results of a simulation in which the refractive index of the blue filters are increased 0.15 from that of the simulation illustrated in FIG. 3. As illustrated in FIG. 7, the light entrance efficiency of the blue filters can be improved further, by decreasing the difference between the refractive indices of the green filters and the blue filters as well as the difference between the refractive indices of the red filters and the blue filters.

The device protecting film 23 is formed as a coating film that protects the surface of the semiconductor substrate 22 after wiring steps and the like are completed thereon. The device protecting film 23 functions to protect the semiconductor substrate from mechanical damage, chemical damage, and electrical damage.

The device protecting film 23 is formed to cover the entire surface of the light shielding film (not shown) on the semiconductor substrate 22, for example. The device protecting film 23 is formed by depositing silicon nitride, etc. by the CVD method or the like, under high temperature conditions (500° C. to 800° C., for example). Note that the device protecting film 23 may alternatively be formed by silicon oxide (SiO₂), glass (PSG), polyimide, etc., instead of silicon nitride (Si₃N₄). However, silicon nitride is particularly preferable from the viewpoints of suppressing dispersion of impurities, suppressing entry of ions, and high moisture resistance.

Next, a method for producing the imaging element 20 of the present embodiment will be described.

The imaging element 20 may be produced by any method as long as the configuration described above is achieved. In the present embodiment, the imaging element 20 may be favorably produced by a production method having the steps to be described below.

Specifically, the imaging element 20 of the present embodiment may be produced by a step (also referred to as an “array forming step” hereinafter) of forming the red filters 21R, the green filters 21G, and the blue filters 21B (hereinafter, also referred to as a “color filter array” hereinafter), a step (also referred to as a “photosensitive layer forming step” hereinafter) of forming a photosensitive resin layer on the color filter array, a step (also referred to as a “patterning step” hereinafter) of exposing and developing the photosensitive resin layer in the form of a pattern to expose the peripheries of the red filters 21R, and a step (also referred to as a “gap forming step”) of administering a dry etching process on the color filter array using the patterned photosensitive resin layer as a mask, and removing the portions at the peripheries of the red filters 21R to form gaps.

Hereinafter, each of the aforementioned steps will be described in greater detail.

First, a desired semiconductor substrate 22 is prepared. As illustrated in FIG. 1, the plurality of photodiodes 26R, 26G, and 263 that constitute the light receiving area, the transfer electrodes 29 constituted by polysilicon or the like, and the light shielding film (now shown) formed by tungsten or the like, provided such that only the light receiving surfaces of the photodiodes are exposed, are formed on the semiconductor substrate 22.

The device protecting film 23 formed by silicon nitride is provided on the light shielding film at the side of the semiconductor substrate 22 opposite that on which the photodiodes 26R, 26G, and 26B are formed so as to cover the entire surface of the light shielding film. The device protecting film 23 illustrated in FIG. 1 is formed by silicon nitride at a thickness of 0.70 μm.

### [Array Forming Step]

Next, the color filter array constituted by the red filters 21R, the green filters 21G, and the blue filters 21B is formed on the semiconductor substrate 22, on which the device protecting film 23 has been provided.

As illustrated in FIG. 8, a coloring composition for forming a first coloring layer (a first color, green for example) is coated on the device protecting film 23 by a spin coater. Then, a hot plate is employed to heat the coated film or the ambient temperature to 220° C. for five minutes to cure the coated film, thereby forming a first coloring layer 32.

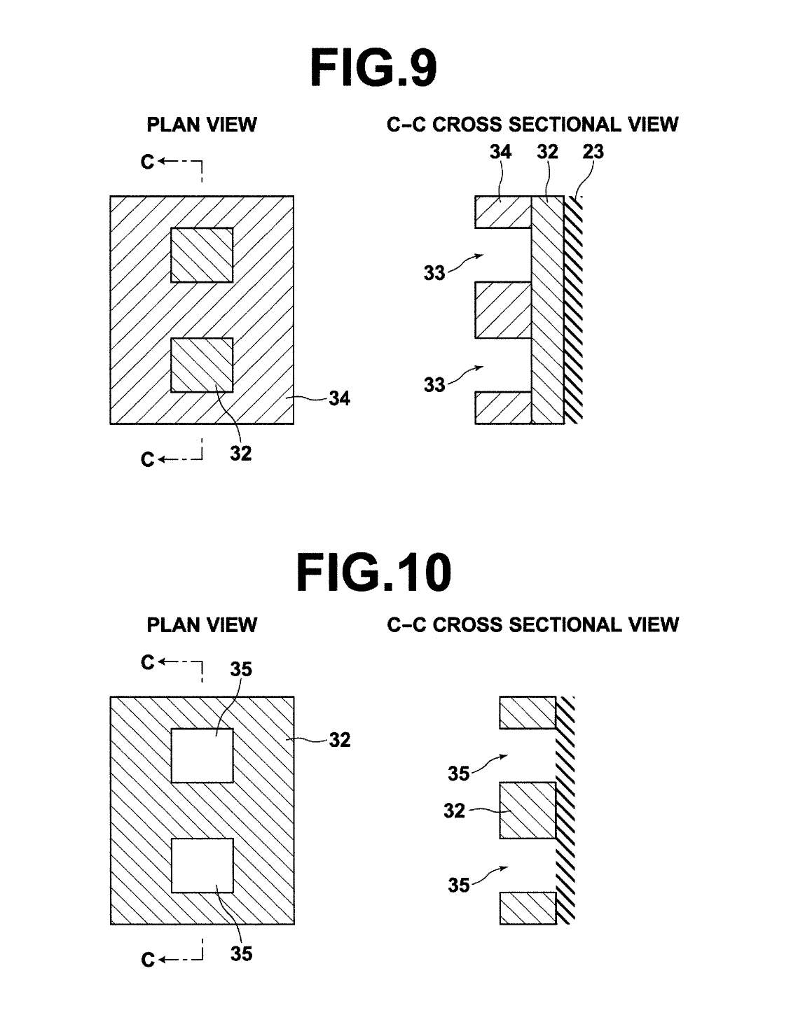

Next, although not illustrated in the drawings, a positive type photoresist is coated on the first coloring layer 32 by a spin coater and pre baking is executed, to form a photoresist layer 34. Then, the photoresist layer 34 formed on the first coloring layer 32 is exposed from above at regions where a second coloring layer (a second color, blue for example) is to be formed by an i line stepper, then a PEB process is performed. Thereafter, a puddle development process is performed using developing liquid and a post baking process is executed, thereby removing the photoresist from regions at which the second coloring layer is to be formed to form openings 33 as illustrated in FIG. 9.

Next, a dry etching apparatus employs a mixed gas (plasma gas) in which fluorocarbon gas and oxygen gas are mixed and desired etching conditions to perform anisotropic etching using the photoresist layer 34 as a mask in order to administer an etching process on the coloring layer 32 at regions at which the second coloring layer is to be formed. The etching conditions at this time may be those for a first etching step that employs the mixed gas consisting of the fluorocarbon gas and oxygen to perform etching to an intermediate portion of the first coloring layer, and a second etching step that employs a second gas that mainly includes nitrogen gas and oxygen gas to perform etching to the substrate.

Next, a solvent or a photoresist removing liquid is utilized to performs photoresist removing process that removes photoresist that remains on the first coloring layer 32. Thereafter, a water removing baking process may be performed to remove the solvent and to remove water. In this manner, the first coloring layer 32 is removed from regions at which the second coloring layer is to be formed, to form openings 35 as illustrated in FIG. 10.

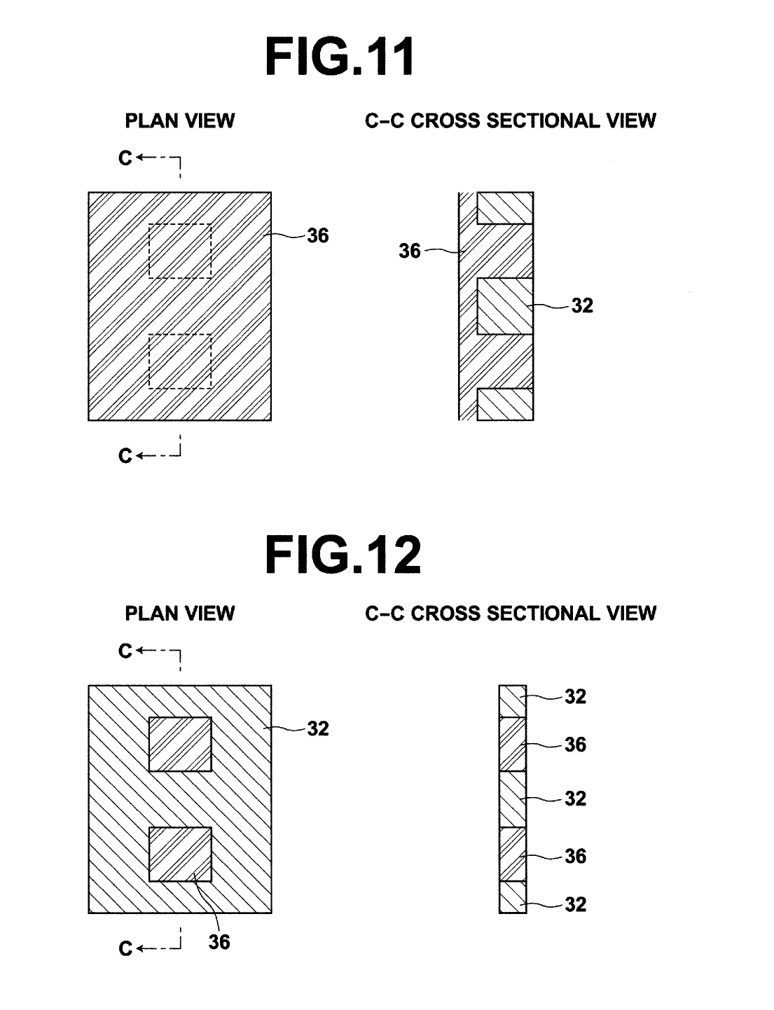

Then, a coloring composition for forming the second coloring layer (a second color, blue for example) is coated on the first coloring layer 32 by a spin coater so as to cover the entirety of the first coloring layer 32 and the openings 35 and also such that the openings 35 are filled with the coloring composition, as illustrated in FIG. 11. Then, the hot plate is employed to administer a post baking process on the coated film, thereby forming the second coloring layer 36.

Next, a CMP apparatus is employed to polish the second coloring layer 36 until the surface of the first coloring layer 32 is exposed, to form the second coloring layer 36 as a pattern as illustrated in FIG. 12. A slurry having fine silica particles dispersed therein is used as an abrasive agent. A polishing device constituted by a polishing cloth may be utilized with a slurry flow rate within a range from 100 ml/min to 250 ml/min, a wafer pressure within a range from 0.2 psi to 5.0 psi, and a retainer ring pressure within a range from 1.0 psi to 2.5 psi. The amount of polishing time is an amount of time until the first coloring layer 32 is exposed, the overpolishing percentage is set to 20%, for example, and the polishing process is completed.

A third coloring layer (a third color) is formed by repeating the same operations as those for forming the second coloring layer 36 described above. Specifically, a positive type photoresist is formed on the first coloring layer 32 again, and photoresist is removed from regions at which the third coloring layer is to be formed by performing exposure and development, to form openings as a pattern. Then, anisotropic etching is executed using the photoresist layer as a mask, to remove the first coloring layer 32 from regions at which the third coloring layer is to be formed, to further form openings. Thereafter, a coloring composition for forming the third coloring layer (a third color, red for example) is coated on the first and second coloring layers 32 and 36 so as to cover the entirety of the first and second coloring layers 32 and 36 and also such that the openings are filled with the coloring composition. Then, the hot plate is employed to administer a post baking process on the coated film, to form the third coloring layer. Thereafter, the CMP apparatus polishes the third coloring layer until the first and second coloring layers 32 and 36 are exposed.

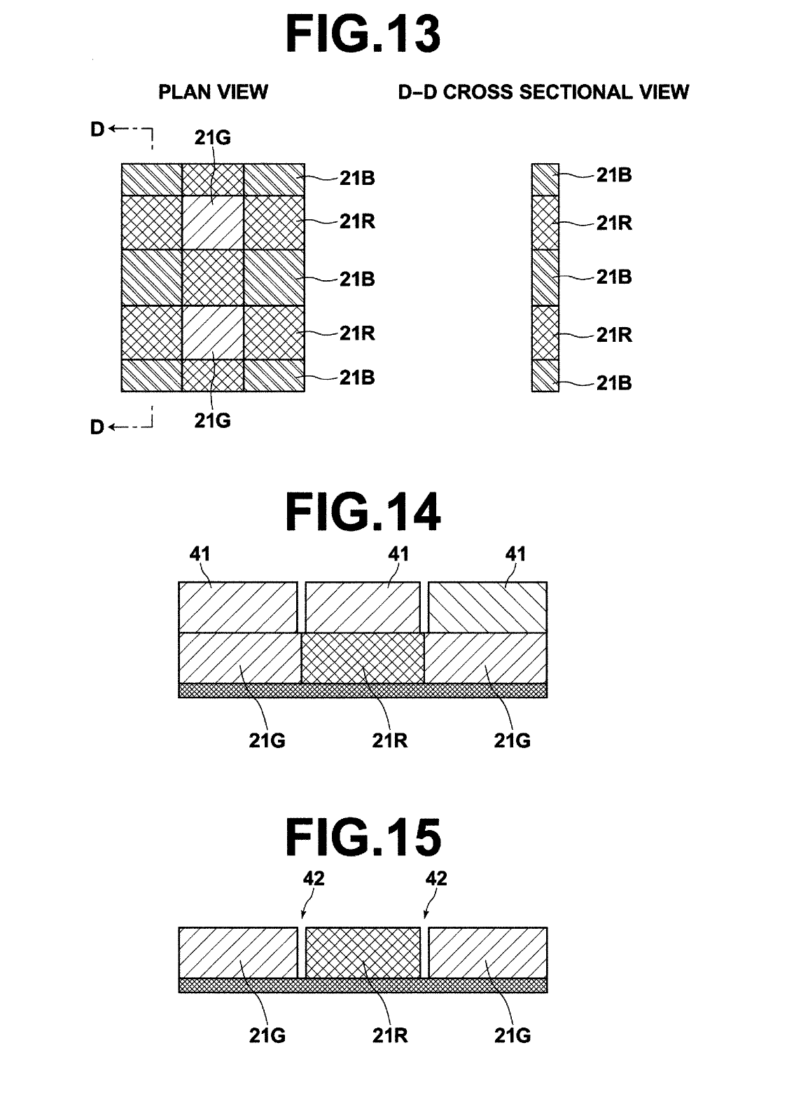

The color filter array constituted by the red filters 21R, the green filters 21G, and the blue filters 21B, such as that illustrated in FIG. 13, is formed by the steps described above.

### [Photosensitive Layer Forming Step]

Next, a positive type photoresist is coated on the entire surface of the color filter array formed in the manner described above, to form a photoresist layer (photosensitive resin layer). It is preferable for a pre baking process to be administered on the formed photoresist layer. A known positive type photoresist may be utilized as the positive type photoresist.

### [Patterning Step]

Next, the photoresist layer is exposed as a pattern via a mask then developed, to form a pattern in which only the peripheries of the red filters are exposed.

Specifically, the positive type photoresist layer is exposed as a pattern by a photolithography method that employs the i line, KrF, and ArF and then developed, to form a space pattern 41 as illustrated in FIG. 14. Thereafter, PEB, alkali development, and a post baking process are performed to obtain a desired mask pattern. Note that it is preferable for the photolithography process to be that which employs KrF and ArF as light sources to form patterns, as more fine processing can be performed. It is more preferable for the photolithography process to be an ArF process from the viewpoint of finer processing.

### [Gap Forming Step]

Next, the color filter array is etched by plasma etching (dry etching process) mainly using a fluorocarbon gas and the aforementioned space pattern 41 as a mask, to remove the peripheral portions of the red filters 21R for a desired width.

Note that it is desirable for the etching process to be that which includes a first etching step, which is a dry etching step that employs a first mixed gas that includes a fluorine series gas and oxygen gas to remove a portion of the coloring layers, and a second etching step, which is a dry etching step that employs a second mixed gas that includes nitrogen gas and oxygen gas to remove the remaining coloring layers, in order to form the exposed portions of the substrate as a pattern. By setting the etching conditions to be those in which the second etching step employs the second gas that includes nitrogen gas and oxygen gas in this manner, the substrate being shaved away can be suppressed. As a result, control of shaving of the substrate can be managed accurately.

Next, after the dry etching processes are completed, the photoresist is removed with an organic solvent or the like, and the color filter array, in which gaps 42 are formed only at the peripheries of the red filters 21R as illustrated in FIG. 15, is obtained. After the etching is completed, the resist (the cured photosensitive resin layer) which was used as a mask is removed by a dedicated removing liquid or an organic solvent. In the case that the second etching step that employs the second gas that includes nitrogen gas and oxygen gas is performed, removal of the photoresist layer using the removing liquid or organic solvent is facilitated.

Thereafter, a material having a refractive index lower than those of the red filters 21R, the green filters 21G, and the blue filters 21B (a fluorine series coating material, for example) is coated on the color filter array so as to fill the gaps 42. Then a baking process is administered for 10 minutes at 200° C., for example, to form the low refractive index partition walls 26 only at the peripheries of the red filters 21R, as illustrated in FIG. 2.

In addition, in the imaging element 20 of the above embodiment, the partition walls 26 are formed by the low refractive index material as described above. However, the present invention is not limited to such a configuration, and the partition walls 26 may be formed by air.

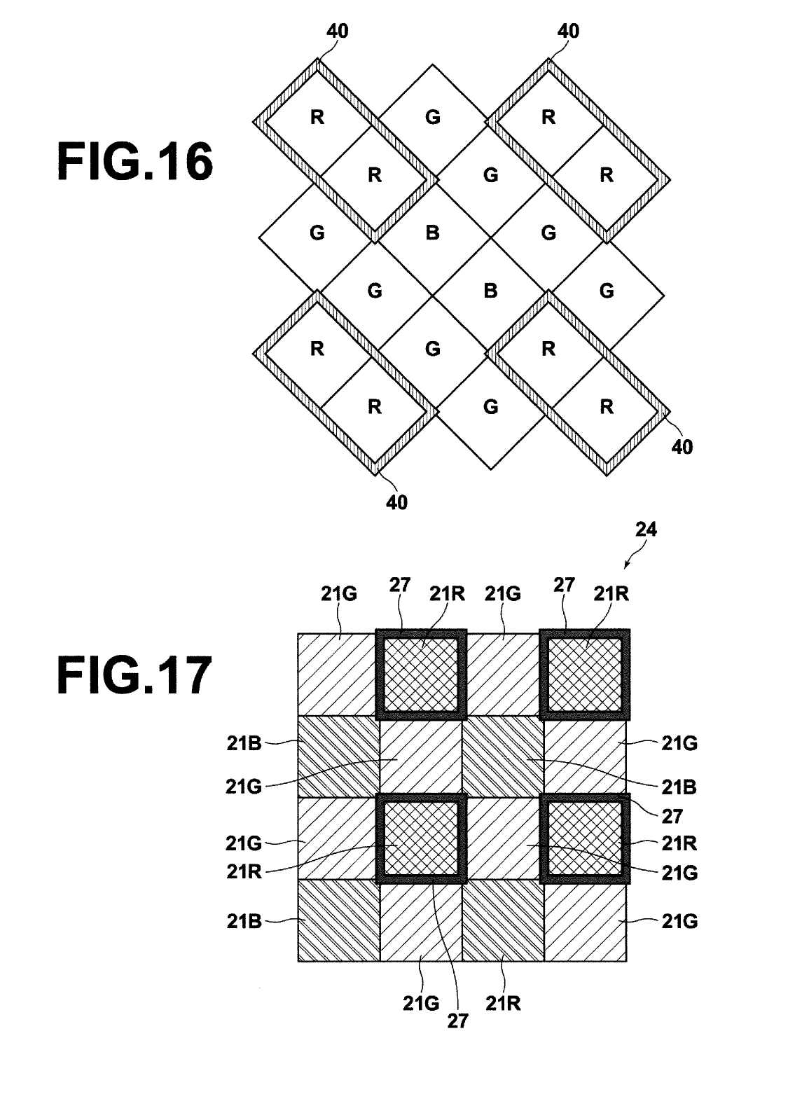

In addition, in the imaging element 20 of the above embodiment, the red filters 21R, the green filters 21G, and the blue filters 21B are in a so called Bayer arrangement. However, the present invention is not limited to such a configuration, and other arrangements may be adopted. Specifically, the color filter layer may be constituted by green filter rows, in which a plurality of green filters G are arranged in a single row, and red/blue filter rows, in which red filter sets constituted by two red filters R and blue filter sets constituted by two blue filters B are alternately arranged in a single row, the green filter rows and the red/blue filter rows being alternately provided in a direction perpendicular to the direction in which the green filter rows and the red/blue filter rows extend, and the direction in which the green filter rows and the red/blue filter rows extend being inclined 45° from the horizontal direction, as illustrated in FIG. 16. In this case as well, partition walls 40 may be provided only at the peripheries of the red filter sets constituted by the two red filters.

In the case that the color filter array has the arrangement illustrated in FIG. 16, the red filters R not only contact the green filters G as in the Bayer arrangement, but also contact the blue filters B. In addition, the red filters R and the green filters G contact each other in units of two pixels. Therefore, conditions for light entering into the red filters R from the green filters G and the blue filters B become more stringent. That is, the advantageous effects of providing the partition walls 40 only at the peripheries of the red filter sets become more prominent compared to the case that filters are arranged in the Bayer arrangement.

In addition, it is desirable for mask members 27 that absorb or reflect light to be provided on the surfaces of the partition walls 26 on the sides thereof that receive light, as illustrated in FIG. 17. Metal films or carbon may be employed as the mask members. By providing the mask members in this manner, cross talk caused by light that enters the partition walls 26 leaking into the red filters R, the green filters G, or the blue filters B can be prevented.

In addition, the imaging element 20 of the above embodiment applies the present invention to a so called front surface irradiation type imaging element. However, the present invention is not limited to application to front surface irradiation type imaging elements, and may also be applied to a so called rear surface irradiation type imaging element as well. A rear surface irradiation type imaging elements is that in which an imaging element is cut thin to 10 μm, and light is received from the rear surface thereof. Rear surface irradiation type imaging elements have high sensitivity due to high quantum efficiency. Ina rear surface irradiation type imaging element without partition walls in the semiconductor layer thereof, the cause of cross talk is almost all determined by the color filter layer thereof. Therefore, an imaging element having little color mixing, superior color reproduction properties, and high sensitivity can be obtained by applying the color filter layer of the present invention to a rear surface irradiation type imaging element.

In addition, the microlens array 25 is provided on the color filter layer 24 in the imaging element of the above embodiment. A configuration may be adopted in which a microlens array is not provided and the color filter array itself functions as a light focusing means. Alternatively, a light focusing means such as a convex or a concave inner lens may be provided between the color filter layer 24 and the device protecting layer 23, as disclosed in Japanese Unexamined Patent Publication No. 2009-111225.

In addition, the imaging element of the above embodiment is that in which the present invention is applied to a so called CMOS sensor. However, it is possible for the present invention to be applied to other types of sensors, and the present invention may be applied to a CCD sensor, for example.

What is claimed is:

1. An imaging element comprising:
a plurality of photoelectric converting elements that receive irradiation of light and convert the light into electrical charges; and
a color filter layer which has a red filter, a green filter, and a blue filter which are respectively provided for each of the photoelectric converting elements;
partition walls having a lower refractive index than those of the red filter, the green filter, and the blue filter being provided only around the peripheries of the red filters.

2. An imaging element as defined in claim 1, further comprising:
mask members that absorb or reflect the light, provided on the surfaces of the partition walls on the sides thereof that receive the light.

3. An imaging element as defined in claim 1, wherein:
the difference between the refractive index of the blue filter and the refractive index of the green filter is 0.05 or less through the entire wavelength range from 500 cm to 650 nm.

4. An imaging element as defined in claim 1, wherein:
the difference between the refractive index of the blue filter and the refractive index of the red filter is 0.15 or less through the entire wavelength range from 500 nm to 650 nm.

5. An imaging element as defined in claim 1, wherein:
the refractive index of the partition walls is 1.4 or less.

6. An imaging element as defined in claim 1, wherein the thickness of the partition walls in a direction perpendicular to the thickness direction of the color filter layer is within a range from 50 nm to 200 nm.

7. An imaging element as defined in claim 1, wherein:
the color filter layer is constituted by green filter rows, in which a plurality of the green filters are arranged in a single row, and red/blue filter rows, in which red filter sets constituted by two of the red filters and blue filter sets constituted by two of the blue filters are alternately arranged in a single row, the green filter rows and the red/blue filter rows being alternately provided in a direction perpendicular to the direction in which the green filter rows and the red/blue filter rows extend.

8. An imaging element as defined in claim 1, wherein:
the partition walls are formed by a low refractive index material having a lower refractive index than the refractive indices of the red filter, the green filter, and the blue filter.

9. An imaging element as defined in claim 1, wherein:
the partition walls are formed by spaces.
